(19) United States
(12) Patent Application Publication
(10) Pub. No.: US 2025/0182806 A1
(43) Pub. Date: Jun. 5, 2025

(54) NON-VOLATILE MEMORY DEVICES AND METHODS OF OPERATING SAME

(71) Applicant: Samsung Electronics Co., Ltd., Suwon-si (KR)

(72) Inventor: Juhyung Kim, Suwon-si (KR)

(21) Appl. No.: 18/952,227

(22) Filed: Nov. 19, 2024

(30) Foreign Application Priority Data
Dec. 1, 2023 (KR) 10-2023-0172730

(51) Int. Cl. G11C 11/22

(52) U.S. Cl. CPC G11C 11/2275; G11C 11/2255; G11C 11/2259

(57) ABSTRACT

A method of programming a ferroelectric NAND-type flash memory device includes applying a program enable voltage to a selected bit line of the memory device concurrently with applying a program inhibition voltage to unselected bit lines of the memory device, during a programming operation. In addition, a first pass voltage having a first magnitude is applied to at least a first word line of the memory device concurrently with: (i) applying a second pass voltage having a second magnitude less than the first magnitude to at least a second word line of the memory device, and (ii) applying a first program voltage having a magnitude greater than the first and second magnitudes to a selected word line of the memory device, during at least a portion of the programming operation.

### REFERENCE TO PRIORITY APPLICATION

This application claims priority under 35 U.S.C. § 119 to Korean Patent Application No. 10-2023-0172730, filed Dec. 1, 2023, the disclosure of which is hereby incorporated herein by reference.

### BACKGROUND

The inventive concept relates to integrated circuit devices and, more particularly, to integrated circuit memory devices and methods of operating same.

Memory devices may be classified into volatile memory devices and non-volatile memory devices. A ferroelectric memory element may be used as a memory element constituting a non-volatile memory device. In the case of general flash memory devices, a shift in the threshold voltage (Vth) is caused by the concentration of electrons in a floating gate or charge trap layer, while in the case of ferroelectric memory devices, a shift in the threshold voltage occurs depending on the polarization direction of a ferroelectric layer.

Recently, with the increase in speed and lower power consumption of electronic products, fast read/write operations and low operating voltages of semiconductor devices embedded in electronic products are required. In response to these demands, research has been conducted on ferroelectric memory, which incorporates ferroelectricity in which internal electric dipole moments are aligned and maintain spontaneous polarization even when an external electric field is not applied to the ferroelectric memory. Moreover, highly integrated ferroelectric memory is emerging as a next-generation memory because the highly integrated ferroelectric memory enables high-speed read and write operations and is non-volatile.

### SUMMARY

The inventive concept relates to a non-volatile memory device and a method of programming a non-volatile ferroelectric memory device, and provides a programming method that advantageously reduces pass voltage disturb and program voltage disturb.

According to an aspect of the inventive concept, a method of operating a non-volatile ferroelectric memory device including ferroelectric NAND flash memory cells includes applying a program inhibition voltage to unselected bit lines, applying a program enable voltage to a selected bit line, applying pass voltages or ground voltages to unselected word lines, and applying a first program voltage to a selected word line.

According to an aspect of the inventive concept, a non-volatile ferroelectric memory device includes a memory cell array connected to a plurality of word lines and a plurality of bit lines and including ferroelectric NAND flash memory cells, a voltage generator configured to generate voltages to be applied to the plurality of word lines, and a control circuit configured to control a program operation for the plurality of memory cells. The control circuit is further configured to control the voltage generator to apply a program inhibition voltage to unselected bit lines, apply a program enable voltage to a selected bit line, apply pass voltages or ground voltages to unselected word lines, and apply a first program voltage to a selected word line.

According to another aspect of the inventive concept, a non-volatile memory device includes a memory cell array connected to a plurality of word lines and a plurality of bit lines and including NAND flash memory cells, a voltage generator configured to generate voltages applied to the plurality of word lines, and a control circuit configured to control a program operation for the plurality of memory cells. The control circuit is further configured to control the voltage generator to apply a program inhibition voltage to unselected bit lines, apply a program enable voltage to a selected bit line, apply pass voltages or ground voltages to unselected word lines, and apply a first program voltage to a selected word line.

According to a further aspect of the inventive concept, a method of operating a ferroelectric NAND-type flash memory device includes applying a program enable voltage to a selected bit line of the memory device concurrently with applying a program inhibition voltage to at least one unselected bit line of the memory device, during a programming operation. In addition, a first pass voltage having a first magnitude is applied to at least a first word line of the memory device concurrently with applying a second pass voltage having a second magnitude less than the first magnitude to at least a second word line of the memory device, and applying a first program voltage (having a magnitude greater than the first and second magnitudes) to a selected word line of the memory device, during at least a portion of the programming operation.

### BRIEF DESCRIPTION OF THE DRAWINGS

Embodiments will be more clearly understood from the following detailed description taken in conjunction with the accompanying drawings in which:

FIG. 1 is a block diagram of a memory device according to an embodiment;

FIG. 2 schematically illustrates the structure of the memory device of FIG. 1, according to an embodiment;

FIG. 3 schematically illustrates a memory cell array of FIG. 1, according to an embodiment;

FIG. 4 is a perspective view illustrating a memory block of FIG. 3, according to an embodiment;

FIG. 5 is a view illustrating a memory cell according to an example embodiment;

FIGS. 6A to 6C are views illustrating a band diagram of a memory cell according to an example embodiment;

FIG. 7 is a view illustrating a three-dimensional V-NAND structure that may be applied to the memory device of FIG. 1;

FIGS. 8A to 8C illustrate voltages applied to word lines, according to example embodiments;

FIGS. 9A to 9C illustrate voltage application timings according to FIGS. 8A to 8C, respectively;

FIG. 10 is a flowchart illustrating a method of operating a memory device in a program execution period (i.e., program operation), according to an example embodiment;

FIG. 11 is a flowchart illustrating a method of operating a memory device, according to an example embodiment;

FIG. 12 illustrates pass voltage disturb related to a word line of a memory device according to an example embodiment;

FIG. 13 is a block diagram illustrating an example of applying a memory system according to embodiments to a solid state drive (SSD) system; and

FIG. 14 is a view illustrating a memory device according to an embodiment.

### DETAILED DESCRIPTION OF THE EMBODIMENTS

Hereinafter, various embodiments of the inventive concept will be described with reference to the accompanying drawings.

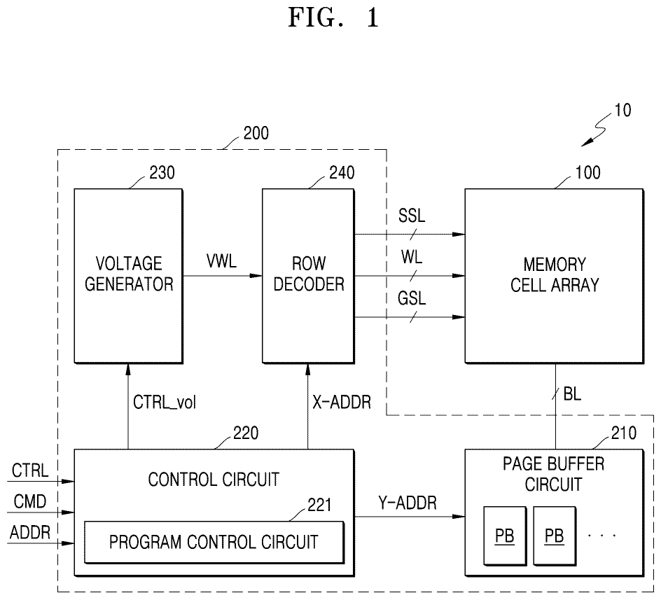

FIG. 1 is a block diagram of a memory device 10 according to an embodiment. Referring to FIG. 1, the memory device 10 may include a memory cell array 100 and a peripheral circuit 200. The peripheral circuit 200 may include a page buffer circuit 210, a control circuit 220, a voltage generator 230, and a row decoder 240. Although not shown in FIG. 1, the peripheral circuit 200 may further include a data input/output circuit or an input/output interface. In addition, the peripheral circuit 200 may further include a column logic, a pre-decoder, a temperature sensor, a command decoder, an address decoder, and the like.

The memory cell array 100 may be electrically connected to the page buffer circuit 210 through a plurality of bit lines BL and may be connected to the row decoder 240 through a plurality of word lines WL, string select lines SSL, and ground select lines GSL, as shown. The memory cell array 100 may include a plurality of memory cells, which may be flash memory cells. Hereinafter, embodiments of the inventive concept will be described in detail taking a case in which the plurality of memory cells are ferroelectric NAND flash memory cells as an example. However, the inventive concept is not limited thereto, and in some embodiments, the plurality of memory cells may be general NAND flash memory cells, or may be resistive memory cells, such as resistive RAM (ReRAM) memory cells, phase change RAM (PRAM) memory cells, or magnetic RAM (MRAM) memory cells, etc.

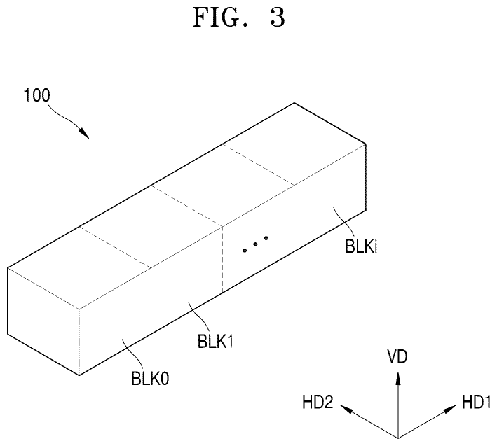

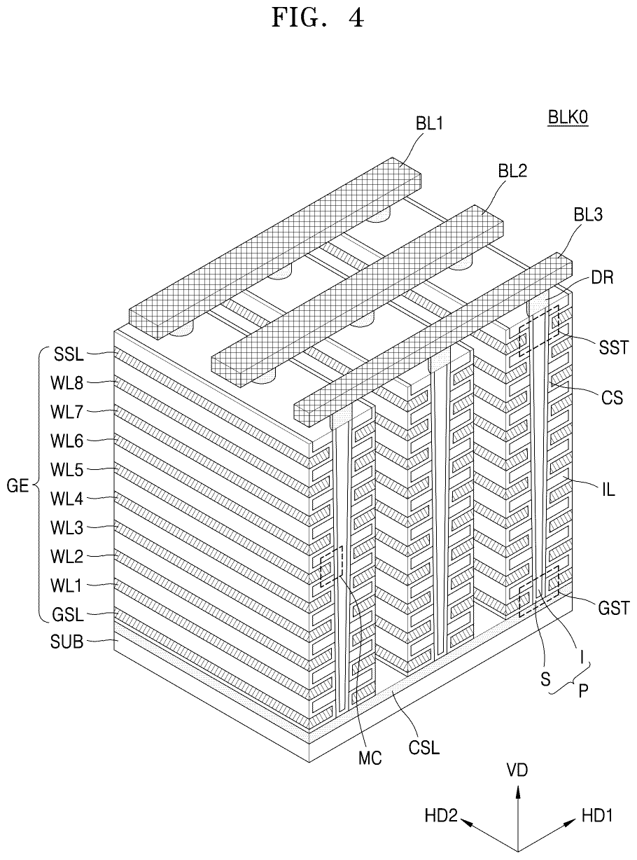

In an embodiment, the memory cell array 100 may include a 3-dimensional (3D) memory cell array, the 3D memory cell array may include a plurality of NAND strings, and each NAND string may include memory cells connected to word lines vertically stacked on a substrate, which will be described in detail with reference to FIGS. 3 and 4. U.S. Pat. Nos. 7,679,133, 8,553,466, 8,654,587, 8,559,235, and US Patent Application Publication No. 2011/0233648 disclose configurations of a three-dimensional memory array in which the three-dimensional memory array is comprised of multiple levels and word lines and/or bit lines are shared between the levels, and are incorporated by reference in their entirety into the present disclosure. However, the inventive concept is not limited thereto, and in some embodiments, the memory cell array 100 may include a two-dimensional (2D) memory cell array, and the 2D memory cell array may include a plurality of NAND strings arranged in row and column directions.

The control circuit 220 may output various types of control signals, for example, a voltage control signal CTRL_vol, a row address X-ADDR, and a column address Y-ADDR, for programing data into the memory cell array 100, reading data from the memory cell array 100, or erasing data stored in the memory cell array 100, based on a command CMD, an address ADDR, and a control signal CTRL. Accordingly, the control circuit 220 may generally control various operations within the memory device 10.

The voltage generator 230 may generate various types of voltages to perform program, read, and erase operations on the memory cell array 100 based on the voltage control signal CTRL_vol. Specifically, the voltage generator 230 may generate a word line voltage VWL, for example, a program voltage, a read voltage, a pass voltage, an erase verification voltage, or a program verification voltage. In addition, the voltage generator 230 may further generate a string select line voltage and a ground select line voltage based on the voltage control signal CTRL_vol.

In response to the row address X-ADDR, the row decoder 240 may select one of a plurality of memory blocks, select one of the word lines WL of the selected memory block, and select one of the string lines SSL. The page buffer circuit 210 may select some of the bit lines BL in response to the column address Y-ADDR. Specifically, the page buffer circuit 210 may operate as a write driver or a sense amplifier depending on the operation mode of the memory device 10. The page buffer circuit 210 may include a plurality of page buffers PB respectively connected to a plurality of bit lines BL.

The control circuit 220 may include a program control circuit 221. The program control circuit 221 may generate the voltage control signal CTRL_vol to generate a program voltage applied to the word line WL during a program operation. When a program operation is performed, memory cells of the memory cell array 100 may be programmed by a program voltage that gradually increases. A method of programming the threshold voltage of memory cells to a target voltage by using the program voltage that gradually increases may be referred to as an Increment Step Pulse Program (ISPP) scheme. When performing a program operation by using the ISPP scheme, a program voltage applied to a word line selected in a plurality of program loops may gradually increase.

In an embodiment, the memory device 10 may include a memory cell array 100 connected to a plurality of word lines and a plurality of bit lines and including ferroelectric NAND flash memory cells, a voltage generator 230 configured to generate a voltage applied to the plurality of word lines, and a control circuit 220 that controls a program operation for a plurality of memory cells. The control circuit 220 may control the voltage generator 230 to apply a program inhibition voltage to unselected bit lines, apply a program enable voltage to a selected bit line, apply pass voltages or ground voltages to unselected word lines, and apply a first program voltage to a selected word line. The unselected word lines may include first word lines, one or more second word lines, and third word lines. The control circuit 220 may control the voltage generator 230 to apply a first pass voltage to the first word lines, apply second pass voltages, which are less than the first pass voltage, to the second word lines, and apply a ground voltage to the third word lines. The second pass voltages may be different from each other. For example, the second pass voltages may increase toward the selected word line. That is, the second pass voltages may be larger as they are adjacent to the selected word line. The first word lines may be higher word lines than the selected word line, the second word lines may be lower word lines than the selected word line, and the third word lines may be lower word lines than the second word lines. The number of second word lines may be three or less. The memory device 10 may be programmed sequentially starting from a lower word line. For example, the control circuit 220 may control the voltage generator 230 to apply a second program voltage to a newly selected word line and to apply the largest pass voltage among the second pass voltages to a previously selected word line. In this case, the newly selected word line may be an upper word line adjacent to the selected word line.

In another embodiment, the memory device 10 may include a memory cell array 100 connected to a plurality of word lines and a plurality of bit lines and including NAND flash memory cells, a voltage generator 230 configured to generate a voltage applied to the plurality of word lines, and a control circuit 220 that controls a program operation for a plurality of memory cells. The control circuit 220 may control the voltage generator 230 to apply a program inhibition voltage to unselected bit lines, apply a program enable voltage to a selected bit line, apply pass voltages or ground voltages to unselected word lines, and apply a first program voltage to a selected word line. The unselected word lines may include first word lines, one or more second word lines, and third word lines. The control circuit 220 may control the voltage generator 230 to apply a first pass voltage to the first word lines, apply second pass voltages, which are less than the first pass voltage, to the second word lines, and apply a ground voltage to the third word lines. The second pass voltages may be different from each other. For example, the second pass voltages may increase toward the selected word line. The first word lines may be higher word lines than the selected word line, the second word lines may be lower word lines than the selected word line, and the third word lines may be lower word lines than the second word lines. The number of second word lines may be three or less. The memory device 10 may be programmed sequentially starting from a lower word line. For example, the control circuit 220 may control the voltage generator 230 to apply a second program voltage to a newly selected word line and to apply the largest pass voltage among the second pass voltages to a previously selected word line. In this case, the newly selected word line may be an upper word line adjacent to the selected word line.

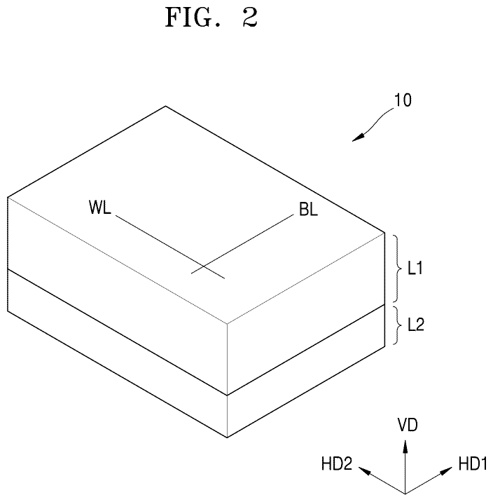

FIG. 2 schematically illustrates the structure of the memory device 10 of FIG. 1, according to an embodiment. Referring to FIG. 2, the memory device 10 may include a first semiconductor layer L1 and a second semiconductor layer L2, and the first semiconductor layer L1 may be stacked in a vertical direction VD with respect to the second semiconductor layer L2. Specifically, the second semiconductor layer L2 may be disposed below the first semiconductor layer L1 in the vertical direction VD, and accordingly, the second semiconductor layer L2 may be disposed close to an external substrate.

In an embodiment, the memory cell array 100 of FIG. 1 may be formed in the first semiconductor layer L1, and the peripheral circuit 200 of FIG. 1 may be formed in the second semiconductor layer L2. Accordingly, the memory device 10 may have a structure in which the memory cell array 100 is disposed above the peripheral circuit 200, that is, a cell over periphery (COP) structure. The COP structure may effectively reduce the horizontal area of the memory device 10 (i.e., layout footprint) and improve the overall integration of the memory device 10.

In an embodiment, the second semiconductor layer L2 may include a substrate, and the peripheral circuit 200 may be formed in the second semiconductor layer L2 by forming transistors and metal patterns for wiring the transistors on the substrate. After the peripheral circuit 200 is formed in the second semiconductor layer L2, the first semiconductor layer L1 including the memory cell array 100 may be formed, and metal patterns may be formed to electrically connect the word lines WL and bit lines BL of the memory cell array 100 to the peripheral circuit 200 formed in the second semiconductor layer L2. For example, the bit lines BL may extend in a first horizontal direction HD1, and the word lines WL may extend in a second horizontal direction HD2.

FIG. 3 schematically illustrates the memory cell array 100 of FIG. 1, according to an embodiment. Referring to FIG. 3, the memory cell array 100 may include a plurality of memory blocks BLK0 to BLKi, where i may be a positive integer. Each of the plurality of memory blocks BLK0 to BLKi may have a 3D structure (or a vertical structure). In particular, each of the plurality of memory blocks BLK0 to BLKi may include a plurality of NAND strings extending in the vertical direction VD. In this case, the plurality of NAND strings may be provided to be spaced apart by a certain distance in the first and second horizontal directions HD1 and HD2. The plurality of memory blocks BLK0 to BLKi may be selected by the row decoder 240 in FIG. 1. For example, the row decoder 140 may select a memory block corresponding to a block address from among the memory blocks BLK0 to BLKi.

FIG. 4 is a perspective view illustrating the memory block BLK0 of FIG. 3, according to an embodiment. Referring to FIG. 4, the memory block BLK0 is formed in a direction perpendicular to a substrate SUB. The substrate SUB is of a first conductivity type (e.g., p-type), and select lines GSL and SSL and word lines WL1 to WL8 extend in the second horizontal direction or second direction HD2 on the substrate SUB. In an embodiment, a common source line CSL doped with impurities of a second conductivity type (e.g., n-type) may be provided on the substrate SUB. In an embodiment, the substrate SUB may include polysilicon, and a plate-shaped common source line CSL may be disposed on the substrate SUB. A plurality of insulating films IL extending in the second horizontal direction HD2 are sequentially provided on the substrate SUB, and the plurality of insulating films IL are spaced apart from each other by a certain distance in the vertical direction VD. For example, the plurality of insulating films IL may include an insulating material, such as silicon oxide.

A plurality of pillars P sequentially disposed in the first horizontal direction or first direction HD1 and penetrating the plurality of insulating films IL in the vertical direction VD are provided on the substrate SUB. For example, the plurality of pillars P may penetrate the plurality of insulating films IL to contact the substrate SUB. Specifically, a surface layer S of each pillar P may include the first type of silicon material and function as a channel region. In some embodiments, the pillar P may be referred to as a channel structure or a vertical channel structure. The inner layer I of each pillar P may include an insulating material, such as silicon oxide or an air gap.

A polarization layer may be provided along exposed surfaces of the insulating films IL, the pillars P, and the substrate SUB. The polarization layer may include a gate insulating layer, a ferroelectric layer, and a blocking insulating layer. In some embodiments, the ferroelectric layer may include hfO₂-based materials (e.g., HZO, HSO, and HAO) or AlScN. In some embodiments, the gate insulating layer may have an oxide-nitride-oxide (ONO) structure. In some embodiments, the gate insulating layer may be excluded. In addition, on an exposed surface of the polarization layer, a gate electrode GE, such as select lines GSL and SSL and word lines WL1 to WL8, is provided. The number of ground select lines GSL, word lines WL1 to WL8, and string select lines SSL may vary depending on embodiments.

Drains DR or drain contacts are provided on the plurality of pillars P, respectively. For example, the drains DR or drain contacts may include a silicon material doped with impurities of the second conductivity type. Bit lines BL1 to BL3 extending in the first horizontal direction HD1 and spaced apart from each other by a certain distance in the second horizontal direction HD2 are provided on the drains DR.

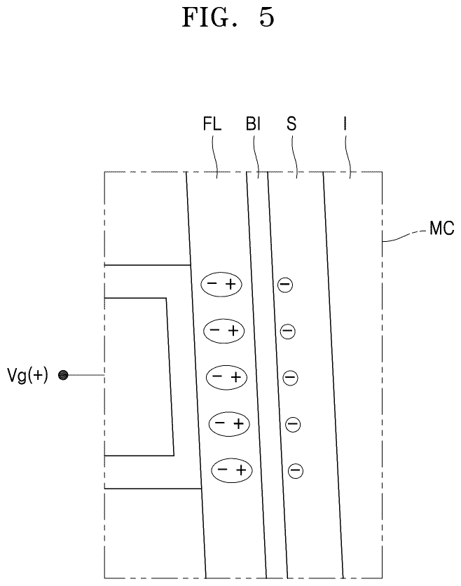

A memory cell MC may be formed at a point where the gate electrode GE intersects with the polarization layer. FIG. 5 is a view illustrating a memory cell according to an example embodiment. FIG. 5 may be explained below with reference to FIG. 4. Referring to FIG. 5, when a positive gate voltage Vg is applied to the gate electrode GE, polarization may occur in a ferroelectric layer FL. That is, a cathode may be formed in a direction of the gate electrode GE and an anode may be formed in a blocking insulation layer BI. Due to ferroelectric properties, the polarization of the ferroelectric layer FL may be maintained even when the voltage applied to the gate electrode GE is blocked/removed. Moreover, due to the polarization of the ferroelectric layer FL, charges may be induced in the surface layer S functioning as a channel region. Therefore, even when a relatively low voltage is applied to the gate electrode GE, a channel may be formed in the memory cell MC, and thus, an effect of lowering the threshold voltage of the memory cell MC may occur.

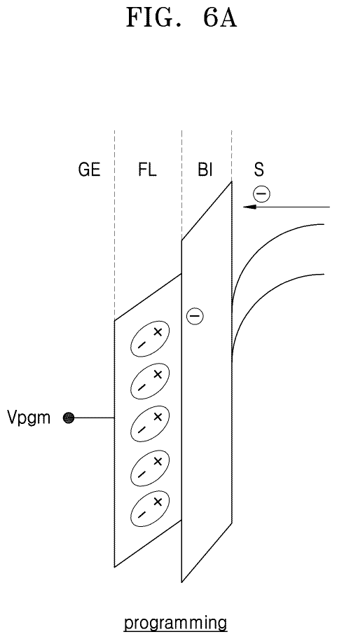

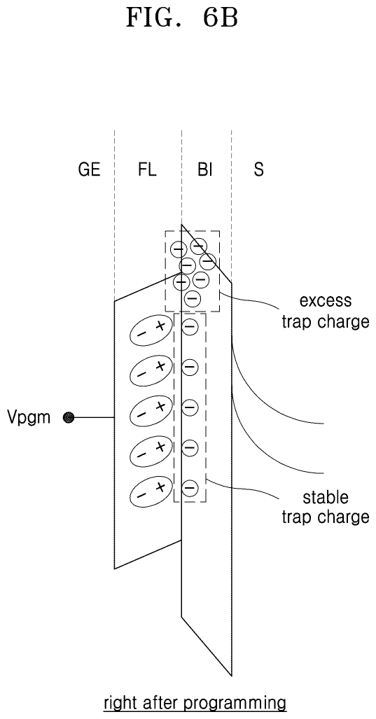

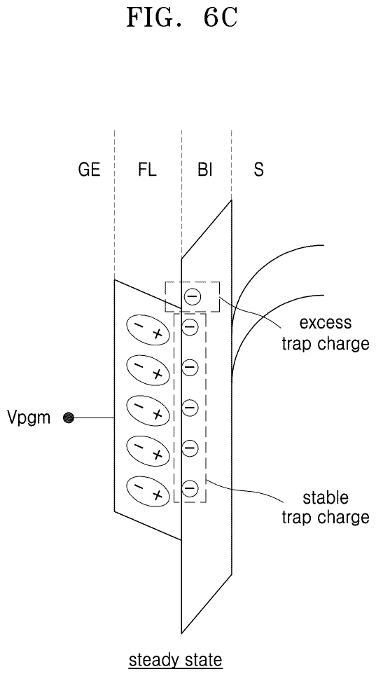

FIGS. 6A to 6C are views illustrating a band diagram of a memory cell according to an example embodiment. FIGS. 6A to 6C may be explained with reference to FIGS. 4 and 5. Referring to FIG. 6A, the memory cell may have a Metal-Ferroelectric-Insulator-Silicon (MFIS) structure. M may refer to the gate electrode GE, F may refer to the ferroelectric layer FL, I may refer to the blocking insulating layer BI, and S may refer to the surface layer S that functions as a channel region. In some embodiments, the memory cell may have a MIFIS structure. That is, a gate insulating layer may be formed between the gate electrode GE and the ferroelectric layer FL.

Referring to FIG. 6A, a program operation on a memory cell may be performed by applying a program voltage Vpgm to the gate electrode GE. When a positive program voltage Vpgm is applied to the gate electrode GE, polarization may be formed in the ferroelectric layer FL, and due to the polarization, charges may be induced in the surface layer S close to the blocking insulating layer BI. In addition, some charges may be trapped between the ferroelectric layer FL and the blocking insulating layer BI.

Referring to FIG. 6B, immediately after programming, when the application of the program voltage Vpgm is stopped, stable trap charges and excess trap charges may be trapped adjacent an interface between the ferroelectric layer FL and the blocking insulating layer BI. When the application of the program voltage Vpgm is stopped, the stable trap charges may remain trapped by the polarization of the ferroelectric layer FL and the excess trap charges may gradually escape from the trap state over time.

Referring to FIG. 6C, in a normal state after programming, most of the excess trap charges may be “de-trapped,” and the stable trap charges may remain trapped. De-trapping of excess trap charges may be possible after standing by for a stabilization time post programming. In addition, according to an example embodiment, a de-trapping rate may be accelerated by applying a negative pulse voltage to the gate electrode GE after programming.

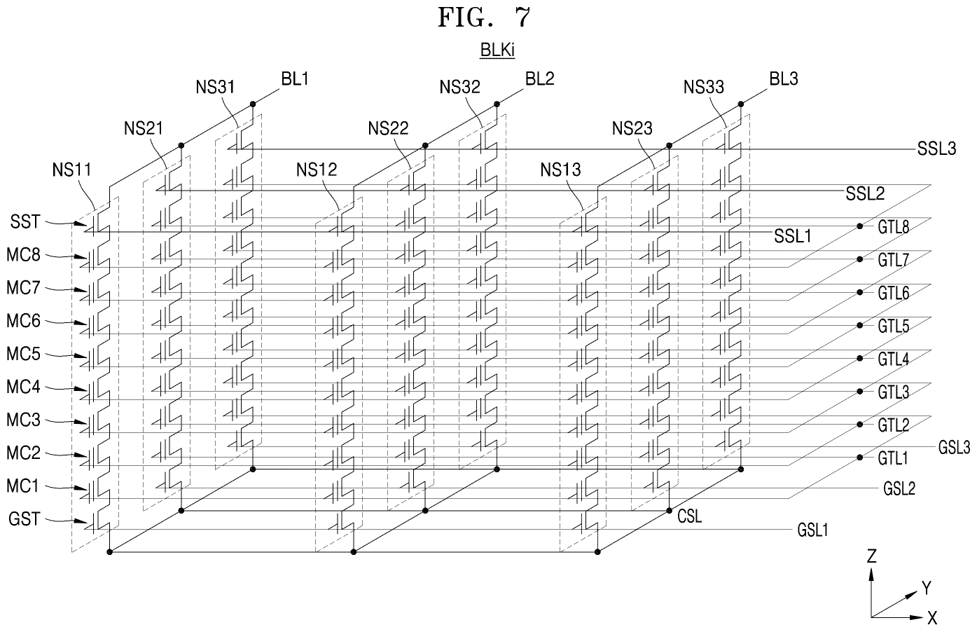

FIG. 7 is a view illustrating a three-dimensional V-NAND structure that may be applied to the memory device 10 of FIG. 1. Referring to FIG. 7, a memory block BLKi may include a plurality of memory NAND strings NS11 to NS33 connected between bit lines BL1, BL2, and BL3 and a common source line CSL. Each of the plurality of memory NAND strings NS11 to NS33 may include a string select transistor SST, a plurality of memory cells MC1 to MC8, and a ground select transistor GST. For brevity of drawings, FIG. 7 illustrates that each of the plurality of memory NAND strings NS11 to NS33 includes eight memory cells MC1 to MC8. However, the inventive concept is not necessarily limited thereto. In addition, the number of memory NAND strings NS11 to NS33 connected to one word line is not limited to the embodiment of FIG. 7 and may vary.

The string select transistor SST may be connected to a corresponding string select line SSL1, SSL2, or SSL3. The plurality of memory cells MC1 to MC8 may be respectively connected to gate lines GTL1 to GTL8 corresponding thereto. The gate lines GTL1 to GTL8 may correspond to word lines, and some of the gate lines GTL1 to GTL8 may correspond to dummy word lines. The ground select transistor GST may be connected to a corresponding ground select line GSL1, GSL2, or GSL3. The string select transistor SST may be connected to a corresponding bit line BL1, BL2, or BL3, and the ground select transistor GST may be connected to the common source line CSL.

The gate lines (for example, GTL1) at the same height may be commonly connected, and each of the ground select transistors GSL1 to GSL3 and the string select lines SSL to SSL3 may be disconnected. FIG. 7 illustrates that the memory block BLKi is connected to the eight gate lines GTL1 to GTL8 and the three bit lines BL1 to BL3. However, the inventive concept is not necessarily limited thereto.

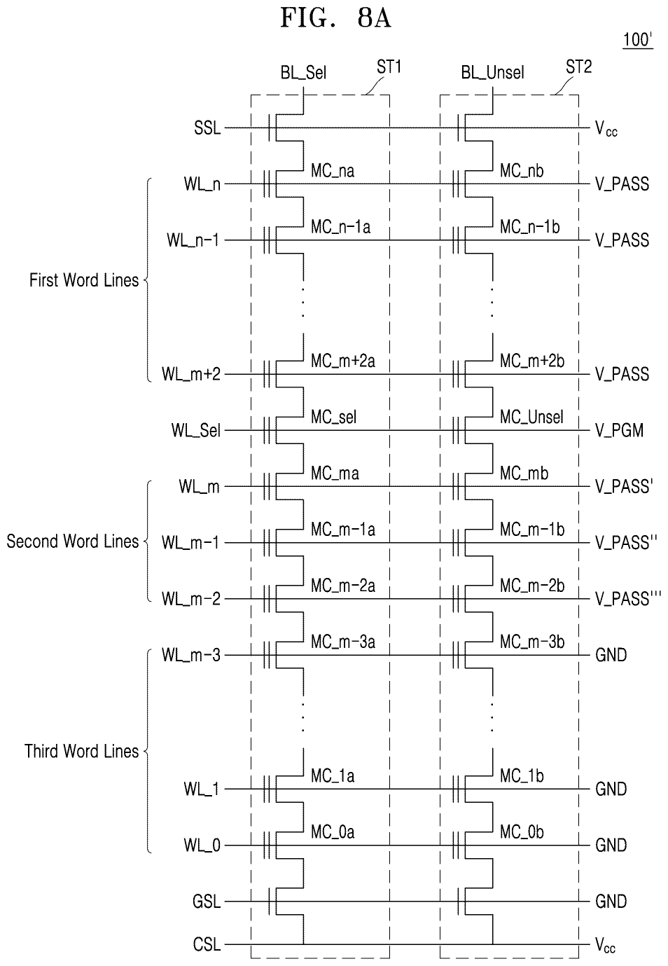

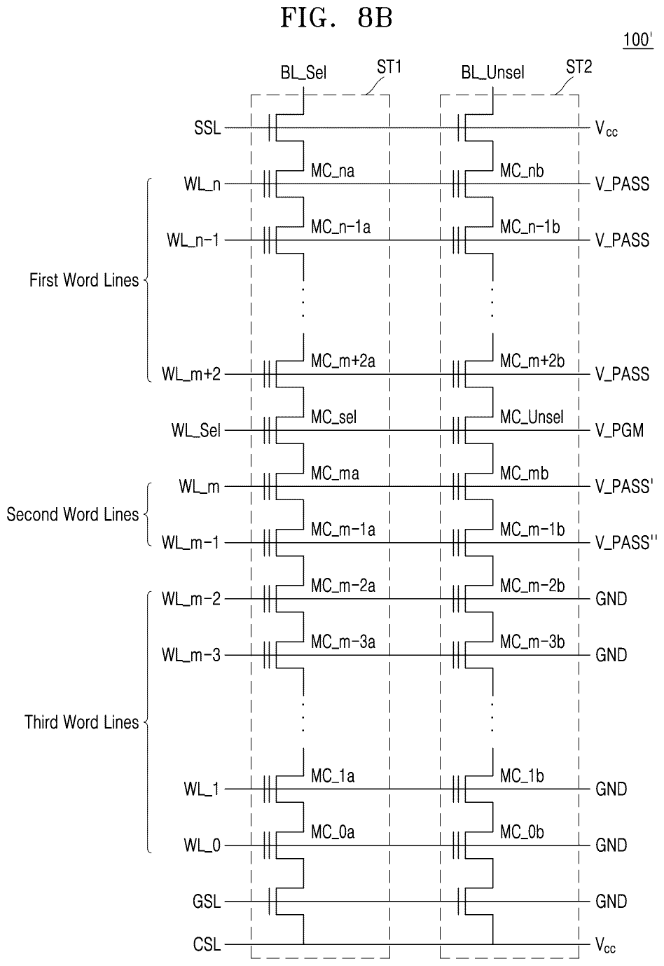

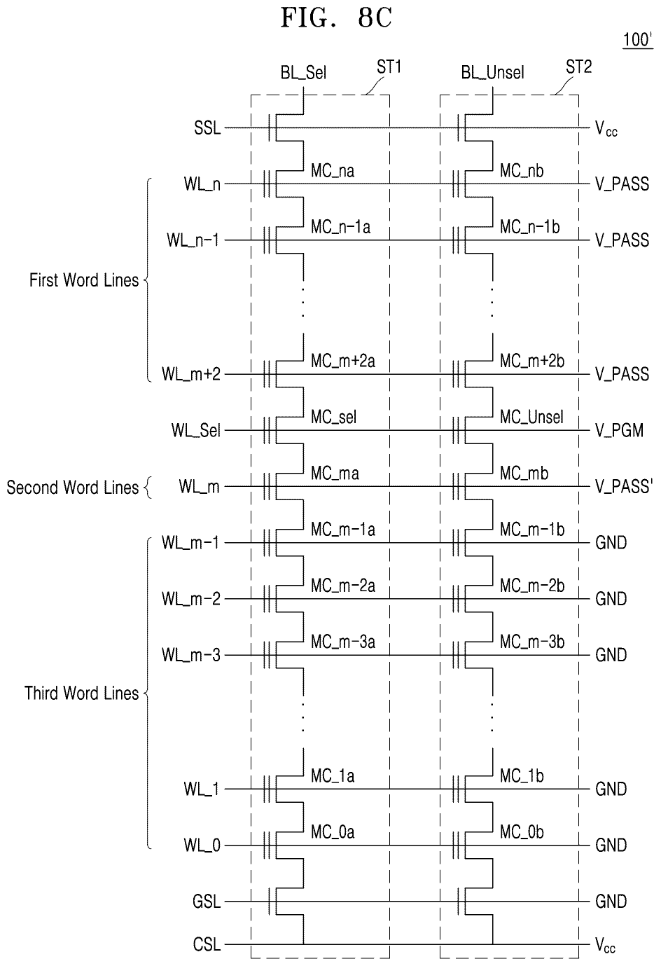

FIGS. 8A to 8C illustrate voltages applied to word lines, according to example embodiments. FIGS. 8A to 8C may be explained with reference to FIG. 1. FIG. 8A illustrates voltages applied to word lines when the number of second word lines is 3, FIG. 8B illustrates voltages applied to word lines when the number of second word lines is 2, and FIG. 8C illustrates voltages applied to word lines when the number of second word lines is 1.

Referring to FIGS. 8A to 8C, a memory cell array 100′ may include first and second strings ST1 and ST2. However, the number of strings is not limited thereto. The first string ST1 and the second string ST2 may be commonly connected to a common source line CSL. The first string ST1 may be connected to a selected bit line BL_Sel, and the second string ST2 may be connected to an unselected bit line BL_Unsel. The first string ST1 may include a selected memory cell MC_sel that is a program target.

String select transistors included in the first string ST1 and the second string ST2 may be connected to a string select line SSL, and ground select transistors included in the first string ST1 and the second string ST2 may be connected to a ground select line GSL. Each of the first string ST1 and the second string ST2 may include memory cells connected to 1st to (n+1)th word lines WL_0 to WL_n. In FIGS. 8A to 8C, it is assumed that the (m+2)th word line WL_m+1 is a selected word line WL_Sel, and it is obvious that any one of the 1st to (n+1)th word lines WL_0 to WL_n may be selected.

The selected word line WL_Sel may be a word line connected to the memory cell MC_Sel that is the program target. Unselected word lines may be different word lines from the selected word line WL_Sel. The selected bit line BL_Sel may be a bit line connected to a string including the memory cell MC_Sel that is the program target, that is, the first string ST1. The unselected bit line BL_Unsel may be a different bit line from the selected bit line BL_Sel. A ground voltage GND may be applied to the selected bit line BL_Sel, and a power supply voltage Vcc may be applied to the unselected bit line BL_Unsel.

Referring to FIG. 8A, voltages applied to the word lines WL_0 to WL_n when the memory device 10 programs the selected memory cell MC_Sel connected to the selected word line WL_Sel are shown. First word lines WL_m+2 to WL_n may refer to upper word lines than the selected word line WL_Sel. Second word lines WL_m−2 to WL_m may refer to lower word lines than and adjacent to the selected word line WL_Sel. Third word lines WL_0 to WL_m−3 may refer to lower word lines than the second word lines WL_m−2 to WL_m. The control circuit 220 may control the voltage generator 230 to apply a first pass voltage V_PASS to the first word lines WL_m+2 to WL_n. For example, the first word lines WL_m+2 to WL_n may all receive the same first pass voltage V_PASS. The selected word line WL_Sel may receive a program voltage V_PGM. The second word lines WL_m−2 to WL_m may receive second pass voltages V_PASS′, V_PASS″, and V_PAS″ that are different. Specifically, the second word line WL_m may receive the second pass voltage V_PASS′. The second word line WL_m−1 may receive the second pass voltage V_PASS″. The second word line WL_m−2 may receive the second pass voltage V_PASS′″. As a word line approaches the selected word line WL_Sel, the word line may receive a greater second pass voltage. For example, the second pass voltages V_PASS′, V_PASS″, and V_PAS″ may have a magnitude order as in Equation 1 below.

V_PASS′>V_PASS″>V_PASS″ [Equation 1]

That is, the magnitude of the second pass voltage may decrease as the distance from a selected word line increases. Accordingly, the occurrence of hot carrier injection (HCI) may be advantageously suppressed. In addition, the second pass voltage V_PASS′ may be less than the first pass voltage V_PASS. The control circuit 220 may control the voltage generator 230 to apply the ground voltage GND to the third word lines WL_0 to WL_m−3. Accordingly, program voltage disturb and pass voltage disturb may be reduced. For example, when programming is sequentially performed starting from the lower word line WL_0, pass voltage disturb for memory cells to which the ground voltage GND is applied may be reduced. Specifically, when programming is performed in the order of the word line WL_0, the word line WL_1, . . . , and the word line WL_n, the program voltage V_PGM may be applied to the selected word line WL_Sel, and the ground voltage GND rather than a pass voltage may be applied to the third word lines WL_0 to WL_m−3, and thus, pass voltage disturb may be reduced.

Referring to FIG. 8B, voltages applied to the word lines WL_0 to WL_n when the memory device 10 programs the selected memory cell MC_Sel connected to the selected word line WL_sel are shown. Descriptions that are redundant with those given above with reference to FIG. 8A may be omitted. First word lines WL_m+2 to WL_n may refer to upper word lines than the selected word line WL_Sel. Second word lines WL_m−1 to WL_m may refer to lower word lines than and adjacent to the selected word line WL_Sel. Third word lines WL_0 to WL_m−2 may refer to lower word lines than the second word lines WL_m−1 to WL_m. The control circuit 220 may control the voltage generator 230 to apply a first pass voltage V_PASS to the first word lines WL_m+2 to WL_n. The second word lines WL_m−1 to WL_m may receive second pass voltages V_PASS′ and V_PASS′ that are different. Specifically, the second word line WL_m may receive the second pass voltage V_PASS′. The second word line WL_m−1 may receive the second pass voltage V_PASS″. As a word line approaches the selected word line WL_Sel, the word line may receive a greater second pass voltage. For example, the second pass voltages V_PASS′ and V_PASS″ may have a magnitude order as in Equation 2 below.

V_PASS′>V_PASS″ [Equation 2]

That is, the magnitude of the second pass voltage may decrease as the distance from the selected word line increases. Accordingly, the occurrence of HCI may be suppressed. In addition, the second pass voltage V_PASS′ may be less than the first pass voltage V_PASS. The control circuit 220 may control the voltage generator 230 to apply the ground voltage GND to the third word lines WL_0 to WL_m−2. Accordingly, program voltage disturb and pass voltage disturb may be reduced.

Referring to FIG. 8C, voltages applied to the word lines WL_0 to WL_n when the memory device 10 programs the selected memory cell MC_Sel connected to the selected word line WL_Sel are shown. Descriptions that are redundant with those given above with reference to FIGS. 8A and 8B may be omitted. First word lines WL_m+2 to WL_n may refer to upper word lines than the selected word line WL_Sel. Second word line WL_m may refer to a lower word line than and adjacent to the selected word line WL_Sel. Third word lines WL_0 to WL_m−1 may refer to lower word lines than the second word line WL_m. The control circuit 220 may control the voltage generator 230 to apply a first pass voltage V_PASS to the first word lines WL_m+2 to WL_n. The second word line WL_m may receive a second pass voltage V_PASS′. The second pass voltage V_PASS′ may be less than the first pass voltage V_PASS. The control circuit 220 may control the voltage generator 230 to apply the ground voltage GND to the third word lines WL_0 to WL_m−1. Accordingly, program voltage disturb and pass voltage disturb may be reduced.

The memory device 10 may be programmed starting from a lower word line. For example, the memory device 10 may be programmed in the order of the word line WL_0, the word line WL_1, . . . , and the word line WL_n. FIGS. 8A to 8C show a section in which the selected word line WL_Sel is programmed, assuming a situation in which programming starts from a lower word line.

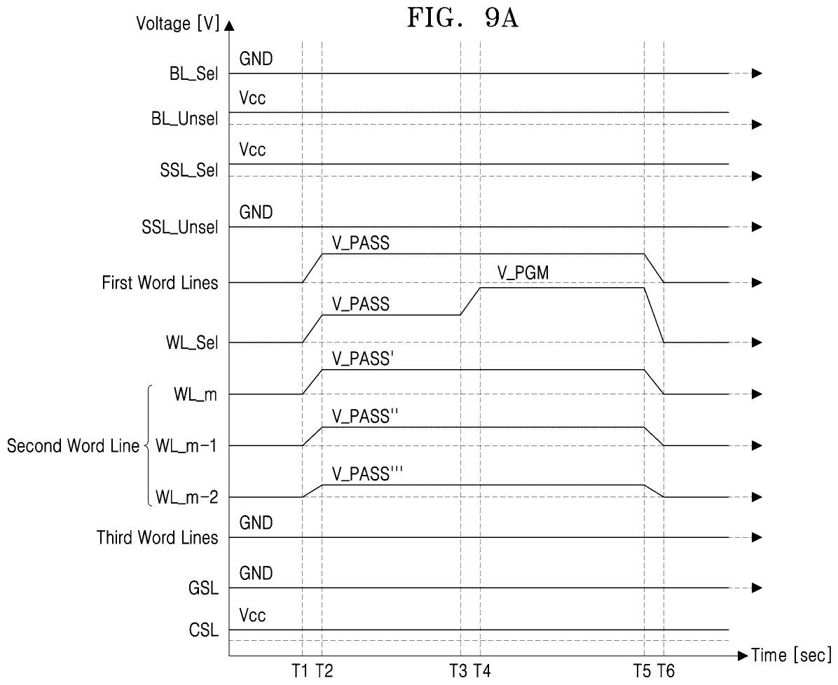

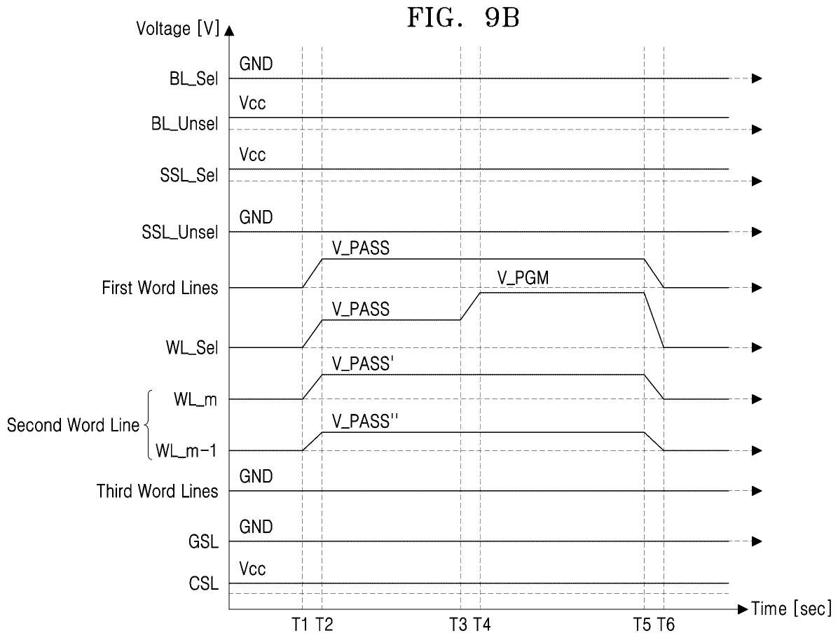

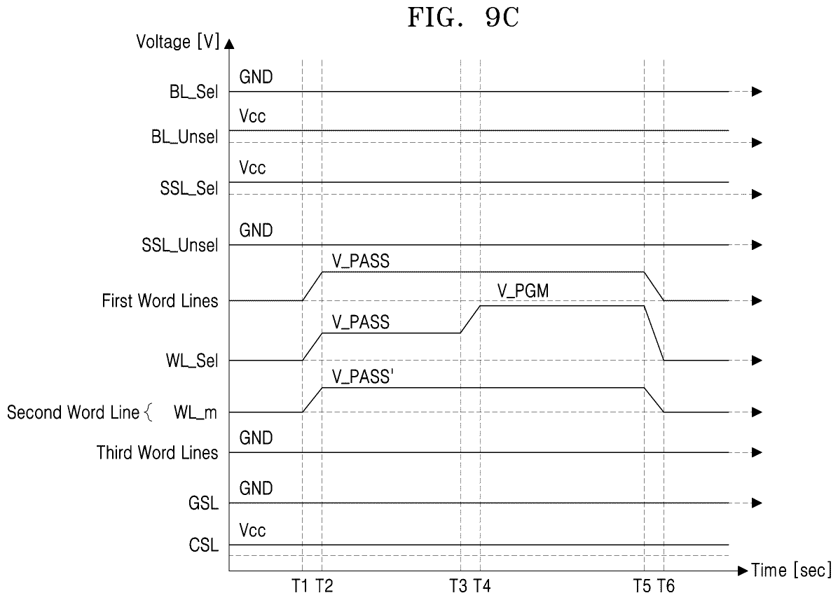

FIGS. 9A to 9C illustrate voltage application timings according to FIGS. 8A to 80, respectively. That is, FIG. 9A illustrates the voltage application timing of FIG. 8A, FIG. 9B illustrates the voltage application timing of FIG. 8B, and FIG. 9C illustrates the voltage application timing of FIG. 8C. Referring to FIGS. 9A to 9C, the ground voltage GND is applied to the selected bit line BL_Sel, and the power supply voltage Vcc is applied to the unselected bit line BL_Unsel. When the string select line SSL is selected (SSL_Sel), the power supply voltage Vcc may be applied thereto, and when the string select line SSL is not selected (SSL_Unsel), the ground voltage GND may be applied thereto. In a program execution period, the first pass voltage V_PASS may be applied to the first word lines WL_m+2 to WL_n. Voltage starts to be applied to the first word lines WL_m+2 to WL_n from T1 so that the first pass voltage V_PASS may be applied from T2 to T5. Program execution ends and 0V may be applied to the first word lines WL_m+2 to WL_n starting from T6. The first pass voltage V_PASS starts to be applied from T1 to the selected word line WL_Sel so that the first pass voltage V_PASS may be applied from T2 to T3. The program voltage V_PGM starts to be applied to the selected word line WL_Sel from T3 so that the program voltage V_PGM may be applied from T4 to T5. Program execution ends and 0V may be applied to the selected word line WL_Sel starting from T6.

Referring to FIG. 9A, the second pass voltages V_PASS′, V_PASS″, and V_PASS″ may start to be applied from T1 to the second word lines WL_m−2 to WL_m, respectively, and may be consistently applied from T2 to T5 to the second word lines WL_m−2 to WL_m, respectively. The first pass voltage V_PASS may be greater than the second pass voltage V_PASS′, the second pass voltage V_PASS′ may be greater than the second pass voltage V_PASS″, and the second pass voltage V_PASS″ may be greater than the second pass voltage V_PASS″. The ground voltage GND may be applied to the third word lines WL_0 to WL_m−3.

Referring to FIG. 9B, the second pass voltages V_PASS′ and V_PASS″ may start to be applied from T1 to the second word lines WL_m−1 to WL_m, respectively, and may be consistently applied from T2 to T5 to the second word lines WL_m−1 to WL_m, respectively. The first pass voltage V_PASS may be greater than the second pass voltage V_PASS′, and the second pass voltage V_PASS′ may be greater than the second pass voltage V_PASS″. The ground voltage GND may be applied to the third word lines WL_0 to WL_m−2. Referring to FIG. 9C, the second pass voltage V_PASS′ may start to be applied from T1 to the second word line WL_m and may be consistently applied from T2 to T5 to the second word line WL_m. The first pass voltage V_PASS may be greater than the second pass voltage V_PASS′. The ground voltage GND may be applied to the third word lines WL_0 to WL_m−1. When the program execution period ends, the voltages of both the bit lines and the word lines may be recovered to an initial voltage.

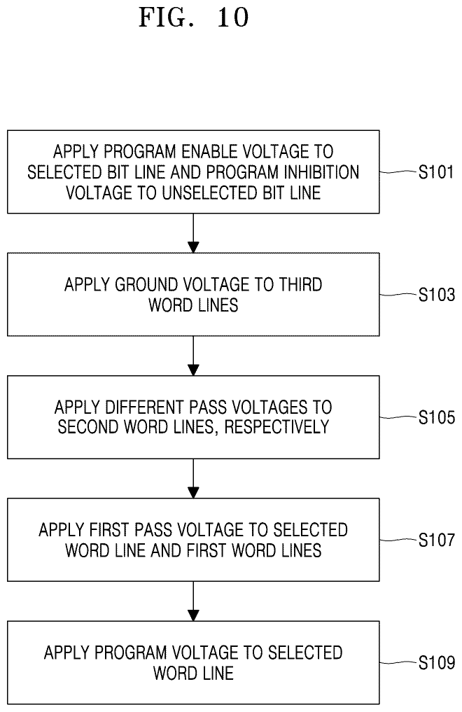

FIG. 10 is a flowchart illustrating a method of operating a memory device in a program execution period, according to an example embodiment. FIG. 10 may be explained with reference to FIGS. 1 and 8A.

Referring to FIG. 10, in operation S101, the memory device 10 may apply a program enable voltage to the selected bit line BL_Sel and a program inhibition voltage to the unselected bit line BL_Unsel. For example, the program enable voltage may be the ground voltage GND. The program inhibition voltage refers to a voltage at which a channel is not formed. For example, the program inhibition voltage may be the power supply voltage VCC.

In operation S103, the memory device 10 may apply the ground voltage GND to the third word lines WL_0 to WL_m−3.

In operation S105, the memory device 10 may apply different pass voltages to the second word lines WL_m−2 to WL_m, respectively. For example, the memory device 10 may apply the second pass voltages V_PASS′, V_PASS″, and V_PASS″ to the second word lines WL_m−2 to WL_m, respectively.

In operation S107, the memory device 10 may apply the first pass voltage V_PASS to the selected word line WL_Sel and the first word lines WL_m+2 to WL_n.

In operation S109, the memory device 10 may apply the program voltage V_PGM to the selected word line WL_Sel.

When the program execution period ends, the voltages of both the bit lines and the word lines may be recovered to an initial voltage.

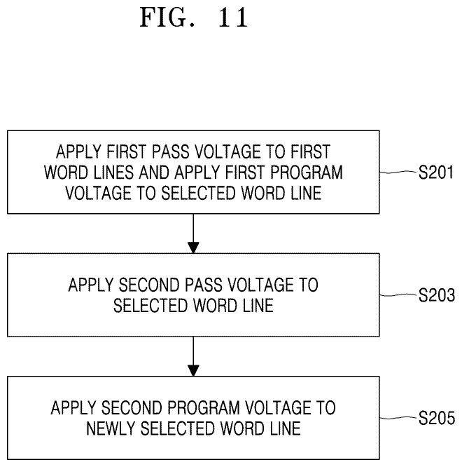

FIG. 11 is a flowchart illustrating a method of operating a memory device, according to an example embodiment. FIG. 11 may be explained with reference to FIGS. 1 and 8A.

The memory device 10 may be programmed starting from a lower word line. For example, the memory device 10 may be programmed in the order of the word line WL_0, the word line WL_1, . . . , and the word line WL_n. In this regard, the memory device 10 may operate as follows.

Referring to FIG. 11, in operation S201, the memory device 10 may apply the first pass voltage V_PASS to the first word lines WL_m+2 to WL_n and apply a first program voltage V_PGM to the selected word line WL_Sel.

In operation S203, the memory device 10 may apply the second pass voltage V_PASS′ to the selected word line WL_Sel. Specifically, after program execution for the selected word line WL_Sel ends, the memory device 10 may apply the second pass voltage V_PASS′ to the selected word line WL_Sel in the program execution period of the word line WL_m+2. That is, the selected word line WL_Sel becomes an unselected word line, and the word line WL_m+2 becomes a newly selected word line WL_Sel′.

In operation S205, the memory device 10 may apply a second program voltage V_PGM′ to the newly selected word line WL_Sel′. The second program voltage V_PGM′ may have the same magnitude as the first program voltage V_PGM.

Accordingly, as described hereinabove with respect to FIGS. 1-11, a method of operating a ferroelectric NAND-type flash memory device can include applying a program enable voltage (e.g., GND) to a selected bit line (e.g., BL_Sel) of the memory device concurrently with applying a program inhibition voltage (e.g., Vcc) to at least one unselected bit line (e.g., BL_Unsel) of the memory device, during a programming operation, which is highlighted by FIGS. 8A-8C, 9A-9C and 10-11, according to some embodiments. In addition, a first pass voltage (e.g., V_PASS) having a first magnitude is applied to at least a first word line of the memory device concurrently with applying a second pass voltage (e.g., V_PASS′) having a second magnitude less than the first magnitude to at least a second word line of the memory device, and applying a first program voltage (V_PGM) having a magnitude greater than the first and second magnitudes to a selected word line (WL_Sel) of the memory device, during at least a portion (e.g., time T4-T5 of FIGS. 9A-9C) of the programming operation.

According to some embodiments, and as illustrated, the operation of applying the first program voltage to the selected word line of the memory device can be preceded by applying the first pass voltage (V_PASS) to the selected word line while the first and second pass voltages are being applied to at least the first word line and at least the second word line, respectively, as shown during time intervals T2-T3 in FIGS. 9A-9C. According to further embodiments, the operation of applying a second pass voltage having a second magnitude less than the first magnitude to at least a second word line of the memory device may be performed concurrently with applying a third pass voltage (e.g., V_PASS″) having a third magnitude less than the second magnitude to at least a third word line of the memory device, as shown by FIGS. 9A-9B. And, in still further embodiments, the operation of applying a third pass voltage having a third magnitude less than the second magnitude to at least a third word line of the memory device is performed concurrently with applying a fourth pass voltage (e.g., V_PASS′″) having a fourth magnitude less than the third magnitude to at least a fourth word line of the memory device, as shown by FIG. 9A.

As further illustrated, the selected bit line of the memory device may correspond to a selected NAND-type string of ferroelectric memory cells within the memory device, and the selected word line of the memory device may be electrically coupled to a selected memory cell within the selected NAND-type string of ferroelectric memory cells. In addition, the first word line of the memory device may be electrically coupled to a first memory cell within the selected NAND-type string of ferroelectric memory cells, the second word line of the memory device may be electrically coupled to a second memory cell within the selected NAND-type string of ferroelectric memory cells, and, within the selected NAND-type string of ferroelectric memory cells, the selected memory cell may extend between the first memory cell and the second memory cell. The selected NAND-type string of ferroelectric memory cells may also include a string selection transistor (having a gate electrode electrically coupled to a string select line SSL); and, within the selected NAND-type string of ferroelectric memory cells, the first memory cell may be located closer to the string selection transistor relative to the second memory cell.

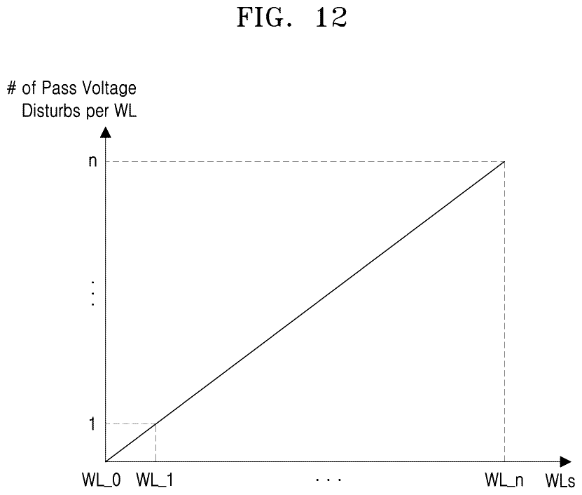

FIG. 12 illustrates pass voltage disturb related to a word line of a memory device according to an example embodiment. FIG. 12 may be explained with reference to FIGS. 1 and 8A. Referring to FIG. 12, the x-axis of the graph represents a word line and the y-axis of the graph represents the number of pass voltage disturbances. The memory device 10 according to an example embodiment may be programmed sequentially starting from the word line WL_0 that is a lower word line. In addition, the memory device 10 may apply the program voltage V_PGM to the selected word line WL_Sel and apply the ground voltage GND to the third word lines WL_0 to WL_m−3 on which programming has already been performed, and thus, the number of pass voltage disturbances of the memory cells MC_0a to MC_m−3a connected to the third word lines WL_0 to WL_m−3 may be reduced. Referring to FIG. 12, the number of pass voltage disturbances of the word line WL_1 is 1 and the number of pass voltage disturbances of the word line WL_2 is 2. Accordingly, the number of pass voltage disturbances of the word line WL_n may be n.

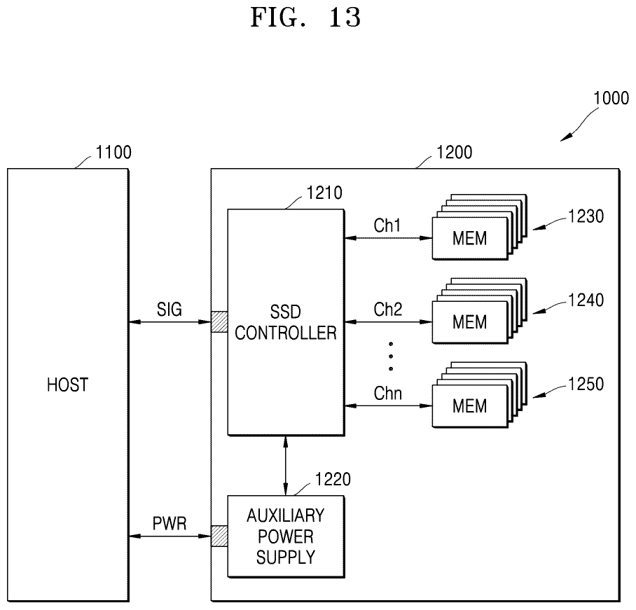

FIG. 13 is a block diagram illustrating an example of applying a memory system according to embodiments to a solid state drive (SSD) system 1000. Referring to FIG. 13, the SSD system 1000 may include a host 1100 and an SSD 1200. The SSD 1200 may exchange a signal SIG with the host 1100 through a signal connector and may receive a power supply PWR through a power connector. The SSD 1200 may include an SSD controller 1210, an auxiliary power supply 1220, and memory devices 1230, 1240, and 1250. The memory devices 1230, 1240, and 1250 may be connected to the SSD controller 1210 through channels Ch1, Ch2, and Chn, respectively.

The memory devices 1230, 1240, and 1250 may be implemented using the memory device 10 described above with reference to FIGS. 1 to 11. Specifically, each of the memory devices 1230, 1240, and 1250 may apply varying magnitude pass voltages or ground voltages to unselected word lines during a program operation.

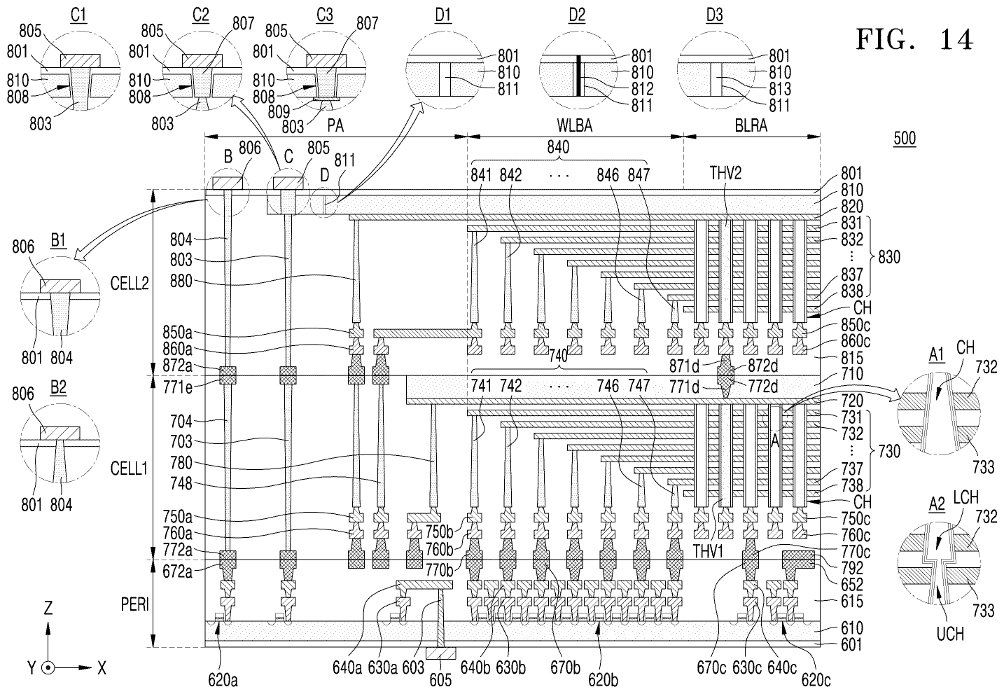

FIG. 14 is a view illustrating a memory device 500 according to some embodiments of the inventive concepts. Referring to FIG. 14, the memory device 500 may have a chip-to-chip (C2C) structure. At least one upper chip including a cell region and a lower chip including a peripheral circuit region PERI may be manufactured separately, and then, the at least one upper chip and the lower chip may be connected to each other by a bonding method to realize the C2C structure. For example, the bonding method may mean a method of electrically or physically connecting a bonding metal pattern formed in an uppermost metal layer of the upper chip to a bonding metal pattern formed in an uppermost metal layer of the lower chip. For example, in a case in which the bonding metal patterns are formed of copper (Cu), the bonding method may be a Cu—Cu bonding method. Alternatively, the bonding metal patterns may be formed of aluminum (Al) or tungsten (W).

The memory device 500 may include the at least one upper chip including the cell region. For example, as illustrated in FIG. 14, the memory device 500 may include two upper chips. However, the number of upper chips is not limited thereto. In the case in which the memory device 500 includes the two upper chips, a first upper chip including a first cell region CELL1, a second upper chip including a second cell region CELL2 and the lower chip including the peripheral circuit region PERI may be manufactured separately, and then, the first upper chip, the second upper chip and the lower chip may be connected to each other by the bonding method to manufacture the memory device 500. The first upper chip may be turned over and then may be connected to the lower chip by the bonding method, and the second upper chip may also be turned over and then may be connected to the first upper chip by the bonding method. Hereinafter, upper and lower portions of each of the first and second upper chips will be defined based on before each of the first and second upper chips is turned over. In other words, an upper portion of the lower chip may mean an upper portion defined based on a +Z-axis direction, and the upper portion of each of the first and second upper chips may mean an upper portion defined based on a −Z-axis direction in FIG. 14. However, embodiments of the inventive concepts are not limited thereto. In certain embodiments, one of the first upper chip and the second upper chip may be turned over and then may be connected to a corresponding chip by the bonding method.

Each of the peripheral circuit region PERI and the first and second cell regions CELL1 and CELL2 of the memory device 500 may include an external pad bonding region PA, a word line bonding region WLBA, and a bit line bonding region BLBA. The peripheral circuit region PERI may include a first substrate 610 and a plurality of circuit elements 620a, 620b and 620c formed on the first substrate 610. An interlayer insulating layer 615 including one or more insulating layers may be provided on the plurality of circuit elements 620a, 620b and 620c, and a plurality of metal lines electrically connected to the plurality of circuit elements 620a, 620b and 620c may be provided in the interlayer insulating layer 615. For example, the plurality of metal lines may include first metal lines 630a, 630b and 630c connected to the plurality of circuit elements 620a, 620b and 620c, and second metal lines 640a, 640b and 640c formed on the first metal lines 630a, 630b and 630c. The plurality of metal lines may be formed of at least one of various conductive materials. For example, the first metal lines 630a, 630b and 630c may be formed of tungsten having a relatively high electrical resistivity, and the second metal lines 640a, 640b and 640c may be formed of copper having a relatively low electrical resistivity.

The first metal lines 630a, 630b and 630c and the second metal lines 640a, 640b and 640c are illustrated and described in the present embodiments. However, embodiments of the inventive concepts are not limited thereto. In certain embodiments, at least one additional metal lines may further be formed on the second metal lines 640a, 640b and 640c. In this case, the second metal lines 640a, 640b and 640c may be formed of aluminum, and at least some of the additional metal lines formed on the second metal lines 640a, 640b and 640c may be formed of copper having an electrical resistivity lower than that of aluminum of the second metal lines 640a, 640b and 640c.

The interlayer insulating layer 615 may be disposed on the first substrate 610 and may include an insulating material such as silicon oxide and/or silicon nitride. Each of the first and second cell regions CELL1 and CELL2 may include at least one memory block. The first cell region CELL1 may include a second substrate 710 and a common source line 720. A plurality of word lines 730 (731 to 738) may be stacked on the second substrate 710 in a direction (i.e., the Z-axis direction) perpendicular to a top surface of the second substrate 710. String selection lines and a ground selection line may be disposed on and under the word lines 730, and the plurality of word lines 730 may be disposed between the string selection lines and the ground selection line. Likewise, the second cell region CELL2 may include a third substrate 810 and a common source line 820, and a plurality of word lines 830 (831 to 838) may be stacked on the third substrate 810 in a direction (i.e., the Z-axis direction) perpendicular to a top surface of the third substrate 810. Each of the second substrate 710 and the third substrate 810 may be formed of at least one of various materials and may be, for example, a silicon substrate, a silicon-germanium substrate, a germanium substrate, or a substrate having a single-crystalline epitaxial layer grown on a single-crystalline silicon substrate. A plurality of channel structures CH may be formed in each of the first and second cell regions CELL1 and CELL2.

In some embodiments, as illustrated in a region ‘A1’, the channel structure CH may be provided in the bit line bonding region BLBA and may extend in the direction perpendicular to the top surface of the second substrate 710 to penetrate the word lines 730, the string selection lines, and the ground selection line. The channel structure CH may include a data storage layer, a channel layer, and a filling insulation layer. The channel layer may be electrically connected to a first metal line 750c and a second metal line 760c in the bit line bonding region BLBA. For example, the second metal line 760c may be a bit line and may be connected to the channel structure CH through the first metal line 750c. The bit line 760c may extend in a first direction (e.g., a Y-axis direction) parallel to the top surface of the second substrate 710.

In some embodiments, as illustrated in a region ‘A2’, the channel structure CH may include a lower channel LCH and an upper channel UCH, which are connected to each other. For example, the channel structure CH may be formed by a process of forming the lower channel LCH and a process of forming the upper channel UCH. The lower channel LCH may extend in the direction perpendicular to the top surface of the second substrate 710 to penetrate the common source line 720 and lower word lines 731 and 732. The lower channel LCH may include a data storage layer, a channel layer, and a filling insulation layer and may be connected to the upper channel UCH. The upper channel UCH may penetrate upper word lines 733 to 738. The upper channel UCH may include a data storage layer, a channel layer, and a filling insulation layer, and the channel layer of the upper channel UCH may be electrically connected to the first metal line 750c and the second metal line 760c. As a length of a channel increases, due to characteristics of manufacturing processes, it may be difficult to form a channel having a substantially uniform width. The memory device 500 according to the present embodiment may include a channel having improved width uniformity due to the lower channel LCH and the upper channel UCH which are formed by the processes performed sequentially.

In the case in which the channel structure CH includes the lower channel LCH and the upper channel UCH as illustrated in the region ‘A2’, a word line located near to a boundary between the lower channel LCH and the upper channel UCH may be a dummy word line. For example, the word lines 732 and 733 adjacent to the boundary between the lower channel LCH and the upper channel UCH may be the dummy word lines. In this case, data may not be stored in memory cells connected to the dummy word line. Alternatively, the number of pages corresponding to the memory cells connected to the dummy word line may be less than the number of pages corresponding to the memory cells connected to a general word line. A level of a voltage applied to the dummy word line may be different from a level of a voltage applied to the general word line, and thus it is possible to reduce an influence of a non-uniform channel width between the lower and upper channels LCH and UCH on an operation of the memory device.

In addition, the number of the lower word lines 731 and 732 penetrated by the lower channel LCH is less than the number of the upper word lines 733 to 738 penetrated by the upper channel UCH in the region ‘A2’. However, embodiments of the inventive concepts are not limited thereto. In certain embodiments, the number of lower word lines penetrated by the lower channel LCH may be equal to or greater than the number of upper word lines penetrated by the upper channel UCH. In addition, structural features and connection relation of the channel structure CH disposed in the second cell region CELL2 may be substantially the same as those of the channel structure CH disposed in the first cell region CELL1.

In the bit line bonding region BLBA, a first through-electrode THV1 may be provided in the first cell region CELL1, and a second through-electrode THV2 may be provided in the second cell region CELL2. As illustrated in FIG. 14, the first through-electrode THV1 may penetrate the common source line 720 and the plurality of word lines 730. In certain embodiments, the first through-electrode THV1 may further penetrate the second substrate 710. The first through-electrode THV1 may include a conductive material. Alternatively, the first through-electrode THV1 may include a conductive material surrounded by an insulating material. The second through-electrode THV2 may have the same shape and structure as the first through-electrode THV1.

In some embodiments, the first through-electrode THV1 and the second through-electrode THV2 may be electrically connected to each other through a first through-metal pattern 772d and a second through-metal pattern 872d. The first through-metal pattern 772d may be formed at a bottom end of the first upper chip including the first cell region CELL1, and the second through-metal pattern 872d may be formed at a top end of the second upper chip including the second cell region CELL2. The first through-electrode THV1 may be electrically connected to the first metal line 750c and the second metal line 760c. A lower via 771d may be formed between the first through-electrode THV1 and the first through-metal pattern 772d, and an upper via 871d may be formed between the second through-electrode THV2 and the second through-metal pattern 872d. The first through-metal pattern 772d and the second through-metal pattern 872d may be connected to each other by the bonding method.

In addition, in the bit line bonding region BLBA, an upper metal pattern 652 may be formed in an uppermost metal layer of the peripheral circuit region PERI, and an upper metal pattern 792 having the same shape as the upper metal pattern 652 may be formed in an uppermost metal layer of the first cell region CELL1. The upper metal pattern 792 of the first cell region CELL1 and the upper metal pattern 652 of the peripheral circuit region PERI may be electrically connected to each other by the bonding method. In the bit line bonding region BLBA, the bit line 760c may be electrically connected to a page buffer included in the peripheral circuit region PERI. For example, some of the circuit elements 620c of the peripheral circuit region PERI may constitute the page buffer, and the bit line 760c may be electrically connected to the circuit elements 620c constituting the page buffer through an upper bonding metal pattern 770c of the first cell region CELL1 and an upper bonding metal pattern 670c of the peripheral circuit region PERI.

Referring still to FIG. 14, in the word line bonding region WLBA, the word lines 730 of the first cell region CELL1 may extend in a second direction (e.g., an X-axis direction) parallel to the top surface of the second substrate 710 and may be connected to a plurality of cell contact plugs 740 (741 to 747). First metal lines 750b and second metal lines 760b may be sequentially connected onto the cell contact plugs 740 connected to the word lines 730. In the word line bonding region WLBA, the cell contact plugs 740 may be connected to the peripheral circuit region PERI through upper bonding metal patterns 770b of the first cell region CELL1 and upper bonding metal patterns 670b of the peripheral circuit region PERI.

The cell contact plugs 740 may be electrically connected to a row decoder included in the peripheral circuit region PERI. For example, some of the circuit elements 620b of the peripheral circuit region PERI may constitute the row decoder, and the cell contact plugs 740 may be electrically connected to the circuit elements 620b constituting the row decoder through the upper bonding metal patterns 770b of the first cell region CELL1 and the upper bonding metal patterns 670b of the peripheral circuit region PERI. In some embodiments, an operating voltage of the circuit elements 620b constituting the row decoder may be different from an operating voltage of the circuit elements 620c constituting the page buffer. For example, the operating voltage of the circuit elements 620c constituting the page buffer may be greater than the operating voltage of the circuit elements 620b constituting the row decoder.

Likewise, in the word line bonding region WLBA, the word lines 830 of the second cell region CELL2 may extend in the second direction (e.g., the X-axis direction) parallel to the top surface of the third substrate 810 and may be connected to a plurality of cell contact plugs 840 (841 to 847). The cell contact plugs 840 may be connected to the peripheral circuit region PERI through an upper metal pattern of the second cell region CELL2 and lower and upper metal patterns and a cell contact plug 348 of the first cell region CELL1.

In the word line bonding region WLBA, the upper bonding metal patterns 770b may be formed in the first cell region CELL1, and the upper bonding metal patterns 670b may be formed in the peripheral circuit region PERI. The upper bonding metal patterns 770b of the first cell region CELL1 and the upper bonding metal patterns 670b of the peripheral circuit region PERI may be electrically connected to each other by the bonding method. The upper bonding metal patterns 770b and the upper bonding metal patterns 670b may be formed of aluminum, copper, or tungsten.

In the external pad bonding region PA, a lower metal pattern 771e may be formed in a lower portion of the first cell region CELL1, and an upper metal pattern 872a may be formed in an upper portion of the second cell region CELL2. The lower metal pattern 771e of the first cell region CELL1 and the upper metal pattern 872a of the second cell region CELL2 may be connected to each other by the bonding method in the external pad bonding region PA. Likewise, an upper metal pattern 772a may be formed in an upper portion of the first cell region CELL1, and an upper metal pattern 672a may be formed in an upper portion of the peripheral circuit region PERI. The upper metal pattern 772a of the first cell region CELL1 and the upper metal pattern 672a of the peripheral circuit region PERI may be connected to each other by the bonding method.

Common source line contact plugs 780 and 880 may be disposed in the external pad bonding region PA. The common source line contact plugs 780 and 880 may be formed of a conductive material such as a metal, a metal compound, and/or doped polysilicon. The common source line contact plug 780 of the first cell region CELL1 may be electrically connected to the common source line 720, and the common source line contact plug 880 of the second cell region CELL2 may be electrically connected to the common source line 820. A first metal line 750a and a second metal line 760a may be sequentially stacked on the common source line contact plug 780 of the first cell region CELL1, and a first metal line 850a and a second metal line 860a may be sequentially stacked on the common source line contact plug 880 of the second cell region CELL2.

Input/output pads 605, 805 and 806 may be disposed in the external pad bonding region PA. Referring to FIG. 14, a lower insulating layer 611 may cover a bottom surface of the first substrate 610, and a first input/output pad 605 may be formed on the lower insulating layer 611. The first input/output pad 605 may be connected to at least one of a plurality of the circuit elements 620a disposed in the peripheral circuit region PERI through a first input/output contact plug 603 and may be separated from the first substrate 610 by the lower insulating layer 611. In addition, a side insulating layer may be disposed between the first input/output contact plug 603 and the first substrate 610 to electrically isolate the first input/output contact plug 603 from the first substrate 610.

An upper insulating layer 801 covering a top surface of the third substrate 810 may be formed on the third substrate 810. A second input/output pad 805 and/or a third input/output pad 806 may be disposed on the upper insulating layer 801. The second input/output pad 805 may be connected to at least one of the plurality of circuit elements 620a disposed in the peripheral circuit region PERI through second input/output contact plugs 803 and 703, and the third input/output pad 806 may be connected to at least one of the plurality of circuit elements 620a disposed in the peripheral circuit region PERI through third input/output contact plugs 804 and 704.

In some embodiments, the third substrate 810 may not be disposed in a region in which the input/output contact plug is disposed. For example, as illustrated in a region ‘B’, the third input/output contact plug 804 may be separated from the third substrate 810 in a direction parallel to the top surface of the third substrate 810 and may penetrate an interlayer insulating layer 815 of the second cell region CELL2 so as to be connected to the third input/output pad 806. In this case, the third input/output contact plug 804 may be formed by at least one of various processes.

In some embodiments, as illustrated in a region ‘B1’, the third input/output contact plug 804 may extend in a third direction (e.g., the Z-axis direction), and a diameter of the third input/output contact plug 804 may become progressively greater toward the upper insulating layer 801. In other words, a diameter of the channel structure CH described in the region ‘A1’ may become progressively less toward the upper insulating layer 801, but the diameter of the third input/output contact plug 804 may become progressively greater toward the upper insulating layer 801. For example, the third input/output contact plug 804 may be formed after the second cell region CELL2 and the first cell region CELL1 are bonded to each other by the bonding method.

In certain embodiments, as illustrated in a region ‘B2’, the third input/output contact plug 804 may extend in the third direction (e.g., the Z-axis direction), and a diameter of the third input/output contact plug 804 may become progressively less toward the upper insulating layer 801. In other words, like the channel structure CH, the diameter of the third input/output contact plug 804 may become progressively less toward the upper insulating layer 801. For example, the third input/output contact plug 804 may be formed together with the cell contact plugs 840 before the second cell region CELL2 and the first cell region CELL1 are bonded to each other.

In certain embodiments, the input/output contact plug may overlap with the third substrate 810. For example, as illustrated in a region ‘C’, the second input/output contact plug 803 may penetrate the interlayer insulating layer 815 of the second cell region CELL2 in the third direction (e.g., the Z-axis direction) and may be electrically connected to the second input/output pad 805 through the third substrate 810. In this case, a connection structure of the second input/output contact plug 803 and the second input/output pad 805 may be realized by various methods.

In some embodiments, as illustrated in a region ‘C1’, an opening 808 may be formed to penetrate the third substrate 810, and the second input/output contact plug 803 may be connected directly to the second input/output pad 805 through the opening 808 formed in the third substrate 810. In this case, as illustrated in the region ‘C1’, a diameter of the second input/output contact plug 803 may become progressively greater toward the second input/output pad 805. However, embodiments of the inventive concepts are not limited thereto, and in certain embodiments, the diameter of the second input/output contact plug 803 may become progressively less toward the second input/output pad 805.

In certain embodiments, as illustrated in a region ‘C2’, the opening 808 penetrating the third substrate 810 may be formed, and a contact 807 may be formed in the opening 808. An end of the contact 807 may be connected to the second input/output pad 805, and another end of the contact 807 may be connected to the second input/output contact plug 803. Thus, the second input/output contact plug 803 may be electrically connected to the second input/output pad 805 through the contact 807 in the opening 808. In this case, as illustrated in the region ‘C2’, a diameter of the contact 807 may become progressively greater toward the second input/output pad 805, and a diameter of the second input/output contact plug 803 may become progressively less toward the second input/output pad 805. For example, the second input/output contact plug 803 may be formed together with the cell contact plugs 840 before the second cell region CELL2 and the first cell region CELL1 are bonded to each other, and the contact 807 may be formed after the second cell region CELL2 and the first cell region CELL1 are bonded to each other.

In certain embodiments illustrated in a region ‘C3’, a stopper 809 may further be formed on a bottom end of the opening 808 of the third substrate 810, as compared with the embodiments of the region ‘C2’. The stopper 809 may be a metal line formed in the same layer as the common source line 820. Alternatively, the stopper 809 may be a metal line formed in the same layer as at least one of the word lines 830. The second input/output contact plug 803 may be electrically connected to the second input/output pad 805 through the contact 807 and the stopper 809.

Like the second and third input/output contact plugs 803 and 804 of the second cell region CELL2, a diameter of each of the second and third input/output contact plugs 703 and 704 of the first cell region CELL1 may become progressively less toward the lower metal pattern 771e or may become progressively greater toward the lower metal pattern 771e.

Meanwhile, in some embodiments, a slit 811 may be formed in the third substrate 810. For example, the slit 811 may be formed at a certain position of the external pad bonding region PA. For example, as illustrated in a region ‘D’, the slit 811 may be located between the second input/output pad 805 and the cell contact plugs 840 when viewed in a plan view. Alternatively, the second input/output pad 805 may be located between the slit 811 and the cell contact plugs 840 when viewed in a plan view.

In some embodiments, as illustrated in a region ‘D1’, the slit 811 may be formed to penetrate the third substrate 810. For example, the slit 811 may be used to prevent the third substrate 810 from being finely cracked when the opening 808 is formed. However, embodiments of the inventive concepts are not limited thereto, and in certain embodiments, the slit 811 may be formed to have a depth ranging from about 60% to about 70% of a thickness of the third substrate 810.

In certain embodiments, as illustrated in a region ‘D2’, a conductive material 812 may be formed in the slit 811. For example, the conductive material 812 may be used to discharge a leakage current occurring in driving of the circuit elements in the external pad bonding region PA to the outside. In this case, the conductive material 812 may be connected to an external ground line.

In certain embodiments, as illustrated in a region ‘D3’, an insulating material 813 may be formed in the slit 811. For example, the insulating material 813 may be used to electrically isolate the second input/output pad 805 and the second input/output contact plug 803 disposed in the external pad bonding region PA from the word line bonding region WLBA. Since the insulating material 813 is formed in the slit 811, it is possible to prevent a voltage provided through the second input/output pad 805 from affecting a metal layer disposed on the third substrate 810 in the word line bonding region WLBA.

Meanwhile, in certain embodiments, the first to third input/output pads 605, 805 and 806 may be selectively formed. For example, the memory device 500 may be realized to include only the first input/output pad 605 disposed on the first substrate 610, to include only the second input/output pad 805 disposed on the third substrate 810, or to include only the third input/output pad 806 disposed on the upper insulating layer 801.

In some embodiments, at least one of the second substrate 710 of the first cell region CELL1 or the third substrate 810 of the second cell region CELL2 may be used as a sacrificial substrate and may be completely or partially removed before or after a bonding process. An additional layer may be stacked after the removal of the substrate. For example, the second substrate 710 of the first cell region CELL1 may be removed before or after the bonding process of the peripheral circuit region PERI and the first cell region CELL1, and then, an insulating layer covering a top surface of the common source line 720 or a conductive layer for connection may be formed. Likewise, the third substrate 810 of the second cell region CELL2 may be removed before or after the bonding process of the first cell region CELL1 and the second cell region CELL2, and then, the upper insulating layer 801 covering a top surface of the common source line 820 or a conductive layer for connection may be formed. The memory cell array 100 of FIG. 1 may be included in the first cell region CELL1 or the second cell region CELL2, and the peripheral circuit 200 may be included in the peripheral circuit region PERI.

While the inventive concept has been particularly shown and described with reference to embodiments thereof, it will be understood that various changes in form and details may be made therein without departing from the spirit and scope of the following claims.

1. A method of operating a ferroelectric NAND-type flash memory device, comprising:
applying a program enable voltage to a selected bit line of the memory device concurrently with applying a program inhibition voltage to unselected bit lines of the memory device, during a programming operation; and
applying a first pass voltage having a first magnitude to at least a first word line of the memory device concurrently with: (i) applying a second pass voltage having a second magnitude less than the first magnitude to at least a second word line of the memory device, and (ii) applying a first program voltage having a magnitude greater than the first and second magnitudes to a selected word line of the memory device, during at least a portion of the programming operation.

2. The method of claim 1, wherein said applying the first program voltage to the selected word line of the memory device is preceded by applying the first pass voltage to the selected word line while the first and second pass voltages are being applied to at least the first word line and at least the second word line, respectively.

3. The method of claim 2, wherein said applying a second pass voltage having a second magnitude less than the first magnitude to at least a second word line of the memory device is performed concurrently with applying a third pass voltage having a third magnitude less than the second magnitude to at least a third word line of the memory device.

4. The method of claim 3, wherein said applying a third pass voltage having a third magnitude less than the second magnitude to at least a third word line of the memory device is performed concurrently with applying a fourth pass voltage having a fourth magnitude less than the third magnitude to at least a fourth word line of the memory device.

5. The method of claim 1, wherein the selected bit line of the memory device corresponds to a selected NAND-type string of ferroelectric memory cells within the memory device; wherein the selected word line of the memory device is electrically coupled to a selected memory cell within the selected NAND-type string of ferroelectric memory cells; wherein the first word line of the memory device is electrically coupled to a first memory cell within the selected NAND-type string of ferroelectric memory cells; wherein the second word line of the memory device is electrically coupled to a second memory cell within the selected NAND-type string of ferroelectric memory cells; and wherein within the selected NAND-type string of ferroelectric memory cells, the selected memory cell extends between the first memory cell and the second memory cell.

6. The method of claim 5, wherein the selected NAND-type string of ferroelectric memory cells includes a string selection transistor; and wherein within the selected NAND-type string of ferroelectric memory cells, the first memory cell is located closer to the string selection transistor relative to the second memory cell.

7. The method of claim 4,
wherein the selected bit line of the memory device corresponds to a selected NAND-type string of ferroelectric memory cells within the memory device;
wherein the selected word line of the memory device is electrically coupled to a selected memory cell within the selected NAND-type string of ferroelectric memory cells;
wherein the first word line of the memory device is electrically coupled to a first memory cell within the selected NAND-type string of ferroelectric memory cells;
wherein the second word line of the memory device is electrically coupled to a second memory cell within the selected NAND-type string of ferroelectric memory cells;
wherein the third word line of the memory device is electrically coupled to a third memory cell within the selected NAND-type string of ferroelectric memory cells;
wherein the fourth word line of the memory device is electrically coupled to a fourth memory cell within the selected NAND-type string of ferroelectric memory cells; and
wherein within the selected NAND-type string of ferroelectric memory cells, the selected memory cell extends between the first memory cell and the second memory cell.

8. The method of claim 7, wherein the selected NAND-type string of ferroelectric memory cells includes a string selection transistor; and wherein within the selected NAND-type string of ferroelectric memory cells, the first memory cell is located closer to the string selection transistor relative to the second memory cell, which is located closer to the string selection transistor relative to the third memory cell, which is located closer to the string selection transistor relative to the fourth memory cell.

9. A non-volatile ferroelectric memory device, comprising:
a memory cell array connected to a plurality of word lines and a plurality of bit lines and including ferroelectric NAND flash memory cells;
a voltage generator configured to generate voltages to be applied to the plurality of word lines; and
a control circuit configured to control a program operation for the plurality of memory cells; and
wherein the control circuit is further configured to control the voltage generator to apply a program inhibition voltage to unselected bit lines, apply a program enable voltage to a selected bit line, apply pass voltages or ground voltages to unselected word lines, and apply a first program voltage to a selected word line.

10. The memory device of claim 9,
wherein the unselected word lines include first word lines, one or more second word lines, and third word lines; and
wherein the control circuit is further configured to control the voltage generator to apply a first pass voltage to the first word lines, apply second pass voltages to the second word lines, wherein the second pass voltages are less than the first pass voltage, and apply a ground voltage to the third word lines.

11. The memory device of claim 10, wherein the second pass voltages are different from each other.

12. The memory device of claim 10, wherein the second pass voltages increase toward the selected word line.

13. The memory device of claim 10, wherein the first word lines are higher word lines than the selected word line, the second word lines are lower word lines than the selected word line, and the third word lines are lower word lines than the second word lines.

14. The memory device of claim 10,
wherein the control circuit is further configured to control the voltage generator to apply a second program voltage to a newly selected word line and apply the greatest pass voltage among the second pass voltages to the selected word line; and
wherein the newly selected word line is an upper word line adjacent to the selected word line.

15. A non-volatile memory device, comprising:
a memory cell array connected to a plurality of word lines and a plurality of bit lines and including NAND flash memory cells;
a voltage generator configured to generate voltages applied to the plurality of word lines; and
a control circuit configured to control a program operation for the plurality of memory cells; and
wherein the control circuit is further configured to control the voltage generator to apply a program inhibition voltage to unselected bit lines, apply a program enable voltage to a selected bit line, apply pass voltages or ground voltages to unselected word lines, and apply a first program voltage to a selected word line.

16. The memory device of claim 15,
wherein the unselected word lines include first word lines, one or more second word lines, and third word lines; and
wherein the control circuit is further configured to control the voltage generator to apply a first pass voltage to the first word lines, apply second pass voltages to the second word lines, wherein the second pass voltages are less than the first pass voltage, and apply a ground voltage to the third word lines.

17. The memory device of claim 16, wherein the second pass voltages are different from each other.

18. The memory device of claim 16, wherein the second pass voltages increase toward the selected word line.

19. The memory device of claim 16, wherein the first word lines are higher word lines than the selected word line, the second word lines are lower word lines than the selected word line, and the third word lines are lower word lines than the second word lines.

20. The memory device of claim 16, wherein a number of second word lines is not greater than 3.

21.-27. (canceled)
